(19) United States
(12) Patent Application Publication
(10) Pub. No.: US 2008/0136429 A1
(43) Pub. Date: Jun. 12, 2008

(54) Probe card of semiconductor test apparatus and method of fabricating the same

(75) Inventors: Young-Soon Lim, Suwon-si (KR); Jung-Woo Sung, Yongin-si (KR); Jung-Mu Lee, Hwaseong-si (KR); Yeon-Suk Shin, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/001,960

(22) Filed: Dec. 12, 2007

(30) Foreign Application Priority Data
Dec. 12, 2006 (KR) 10-2006-0126448

(51) Int. Cl. G01R 1/073; H01S 4/00

(52) U.S. Cl. 324/754; 29/592.1

(57) ABSTRACT

A probe card of a semiconductor test apparatus includes a printed circuit board (PCB) in which a signal wiring and a first ground plate are provided, a needle fixture mounted at the PCB and provided to fix a plurality of needles, a second ground plate provided at the needle fixture, a plurality of signal lines connecting the signal wiring to the plurality of needles corresponding to the signal wiring, a plurality of ground lines connecting the first ground plate to the second ground plate and corresponding to the plurality of signal lines, and a connecting electrode connecting the first ground plate to the second ground plate. A method of fabricating the same is also provided.

### CROSS-REFERENCE TO RELATED APPLICATIONS

This U.S. non-provisional patent application claims priority under 35 U.S.C. § 119 to Korean Patent Application No. 10-2006-0126448, filed on Dec. 12, 2006, the entire contents of which are hereby incorporated by reference.

### FIELD OF INVENTION

The present invention relates to a semiconductor test apparatus and a method of fabricating the same, and, more particularly, to a probe card of a semiconductor test apparatus and a method of fabricating the same.

### BACKGROUND

A semiconductor device is accomplished to serve as one complete semiconductor package through a large number of processes. Generally, these processes can be classified into a semiconductor wafer production process, a semiconductor device fabrication (FAB) process, and an assembly process.

Especially, an electric die sorting (EDS) test is conducted to discriminate whether a plurality of semiconductor devices formed on a semiconductor wafer by means of a semiconductor fabricating process are good or bad. The test of electrical characteristics is aimed at: (1) discriminating whether semiconductor devices formed on a semiconductor wafer are each good or bad, (2) repairing repairable semiconductor devices among bad semiconductor devices, (3) feed-backing problems arising from a semiconductor fabricating process in the early stage, and (4) removing bad semiconductor devices in the early stage to reduce the expenses of assembly and package test.

A semiconductor test apparatus for use in test of electrical characteristics includes a tester, a performance board, a probe card, a chuck, and a prober. The probe card serves to receive an input signal from the tester through the performance board and transmit the input signal to electrode pads of semiconductor devices. Also the probe card serves to transmit an output signal from the electrode pads of semiconductor devices to the tester through the performance board.

FIGS. 1A and 1B are a cross-sectional view and a perspective view, respectively, illustrating a probe card of a conventional semiconductor test apparatus. The probe card can include a printed circuit board (PCB) 10, needle fixtures 20 and 30, a plurality of needles 35, and a plurality of signal lines 52s. For simplification of the figures, only one needle and only one signal line are illustrated in the figures.

A quadrangular lower needle fixture 20 having a predetermined size can be mounted at the center of the PCB 10. The plurality of needles 35 corresponding to electrode pads of semiconductor devices can be arranged on an upper needle fixture 30 to achieve a fixed structure. The upper needle fixture 30 can be mounted on the lower needle fixture 20 to fix the plurality of needles 35. That is, the upper needle fixture 30 can serve to prevent the position variation of the arranged plurality of needles 35 even when an external force is applied to the arranged plurality of needles 35. Each of the plurality of needles 35 corresponding to electrode pads of semiconductor devices can have one end inclined at a predetermined angle, i.e., can exhibit a cantilever shape. Further, each of the plurality of needles 35 can have the other end that is electrically connected to a signal wiring (not shown) included in the PCB 10 by means of the plurality of signal lines 52s. The plurality of signal lines 52s can be connected to the signal wiring in the PCB 10 by means of a solder 50ss. A ground plate 12 can be provided inside the PCB 10. The upper needle fixture 30 can have an opening 30o used to repair the plurality of needles 35.

The foregoing probe card of the conventional semiconductor test apparatus has a structure where there is no reference for a signal line when a signal is transmitted through the signal line. Accordingly, insertion loss arises from the signal line when a signal is transmitted. In addition, the transmitted signal can be distorted due to external environment. The insertion loss and the distortion of the transmitted signal can prevent accurate evaluation of operation of a semiconductor device fabricated in a semiconductor wafer during a test for the semiconductor device. Hence the probe card has been applied to test direct current (DC) of 180 MHz or lower. As the signal of frequency band is higher, the greater the loss arising when the signal is transmitted. Therefore, it is difficult to practically evaluate a semiconductor device for use in high speed operation (e.g., an analog or logic device of 300 MHz or higher).

### SUMMARY OF THE INVENTION

In accordance with one aspect of the present invention there is provided a probe card of a semiconductor test apparatus. The probe card includes: a printed circuit board (PCB) in which a signal wiring and a first ground plate are provided; a needle fixture mounted to the PCB and configured to fix a plurality of needles; a second ground plate provided on the needle fixture; a plurality of signal lines connecting the plurality of needles to corresponding wiring in the signal wiring; a plurality of ground lines connecting the first ground plate to a first position of the second ground plate and corresponding to the plurality of signal lines; and a connecting electrode connecting the first ground plate to a second position of the second ground plate.

The first ground plate can include copper (Cu).

The second ground plate can include copper (Cu).

The needle can include a material selected from a group consisting of tungsten (W), tungsten alloy (W-alloy), and platinum (Pt).

The needle fixture can comprise a lower needle fixture and an upper needle fixture.

The lower needle fixture can include ceramic.

The upper needle fixture can include an opening formed therein to expose the plurality of needles.

The upper needle fixture can include epoxy.

The second ground plate can be mounted on the upper needle fixture.

The second ground plate can be provided between the lower needle fixture and the upper needle fixture.

The signal line can include a material selected from a group consisting of tungsten (W), tungsten alloy (W-alloy), and platinum (Pt).

The ground line can include a material selected from a group consisting of tungsten (W), tungsten alloy (W-alloy), and platinum (Pt).

Each signal line and each ground line that correspond to each other can be insulated with a coaxial cable.

The connecting electrode can include copper (Cu).

In accordance with another aspect of the present invention, there is provided a probe card of a semiconductor test apparatus. The probe card of a semiconductor test apparatus comprises: a printed circuit board (PCB) in which a signal wiring and a first ground plate are provided; a needle fixture mounted to the PCB and configured to fix a plurality of needles, wherein the needle fixture comprises a lower needle fixture and an upper needle fixture and the upper needle fixture includes an opening formed therein to expose the plurality of needles; a second ground plate provided on the needle fixture; a plurality of signal lines connecting the plurality of needles to corresponding wiring in the signal wiring; a plurality of ground lines connecting the first ground plate to a first position of the second ground plate and corresponding to the plurality of signal lines; and a connecting electrode connecting the first ground plate to a second position of the second ground plate, wherein each signal line and each ground line that correspond to each other are insulated with a coaxial cable.

The upper needle fixture can include epoxy.

The second ground plate can be provided between the lower needle fixture and the upper needle fixture.

In accordance with another aspect of the present invention, provided is a method of making a probe card of a semiconductor test apparatus. The method includes: providing a printed circuit board (PCB) having a signal wiring and a first ground plate; mounting a needle fixture to the PCB, which is configured to fix a plurality of needles, wherein the needle fixture comprises a lower fixture and an upper fixture and the upper needle fixture includes an opening formed therein to expose the plurality of needles; providing a second ground plate on the needle fixture; connecting the plurality of needles to corresponding wiring in the signal wiring with a plurality of signal lines; connecting the first ground plate to a first position of the second ground plate and corresponding to the plurality of signal lines with a plurality of ground lines; and connecting the first ground plate to a second position of the second ground plate with a connecting electrode.

The second ground plate can be provided on the upper needle fixture.

The second ground plate can be provided between the lower needle fixture and the upper needle fixture.

### BRIEF DESCRIPTION OF THE DRAWINGS

FIGS. 1A and 1B are a cross-sectional view and a perspective view, respectively, illustrating a probe card of a conventional semiconductor test apparatus.

FIGS. 2A and 2B are a cross-sectional view and a perspective view, respectively, illustrating an embodiment of a probe card of a semiconductor test apparatus according to an aspect of the present invention.

FIGS. 3A and 3B are a cross-sectional view and a top plan view, respectively, illustrating an embodiment of a coated ground line of FIG. 2B.

FIGS. 4A and 4B are a cross-sectional view and a perspective view, respectively, illustrating an embodiment of a probe card of a semiconductor test apparatus according to another aspect of the present invention.

FIGS. 5A and 5B are graphs showing measured signal transmission characteristics of probe cards of semiconductor test apparatuses in the frequency domain according to embodiments of the present invention.

FIGS. 6A and 7A are graphs showing measured signal transmission characteristics of probe cards of conventional semiconductor test apparatuses in the time domain.

FIGS. 6B and 7B are graphs showing measured signal transmission characteristics of probe cards of semiconductor test apparatuses in the time domain according to embodiments of the present invention.

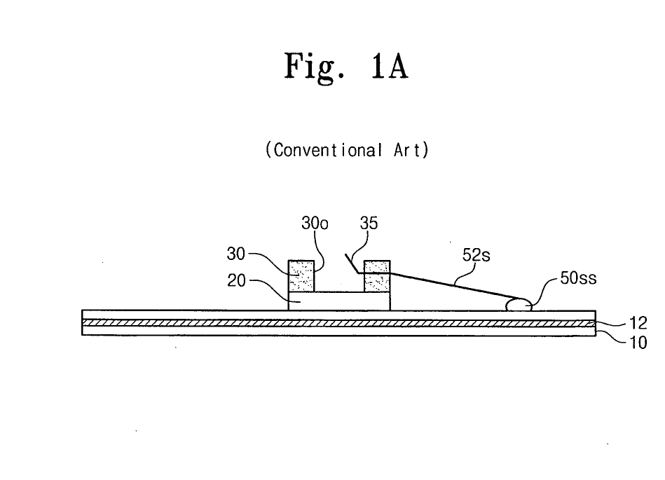

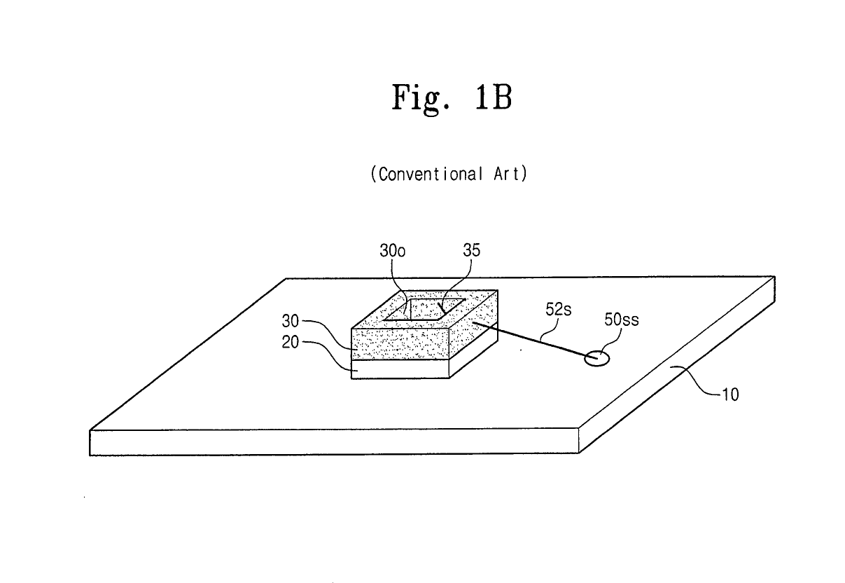

### DETAILED DESCRIPTION OF PREFERRED EMBODIMENTS

Aspects of the present invention will now be described more fully hereinafter with reference to the accompanying drawings, in which preferred embodiments in accordance with the invention are shown. This invention, however, can be embodied in many different forms and should not be construed as limited to the embodiments set forth herein. In the drawings, the thicknesses of layers and regions are exaggerated for clarity.

It will be understood that, although the terms first, second, etc. are be used herein to describe various elements, these elements should not be limited by these terms. These terms are used to distinguish one element from another, but not to imply a required sequence of elements. For example, a first element can be termed a second element, and, similarly, a second element can be termed a first element, without departing from the scope of the present invention. As used herein, the term “and/or” includes any and all combinations of one or more of the associated listed items.

It will be understood that when an element is referred to as being “on” or “connected” or “coupled” to another element, it can be directly on or connected or coupled to the other element or intervening elements can be present. In contrast, when an element is referred to as being “directly on” or “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements, and/or components, but do not preclude the presence or addition of one or more other features, steps, operations, elements, components, and/or groups thereof.

Spatially relative terms, such as “beneath,” “below,” “lower,” “above,” “upper” and the like may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as “below” and/or “beneath” other elements or features would then be oriented “above” the other elements or features. The device may be otherwise oriented (e.g., rotated 90 degrees or at other orientations) and the spatially relative descriptors used herein interpreted accordingly.

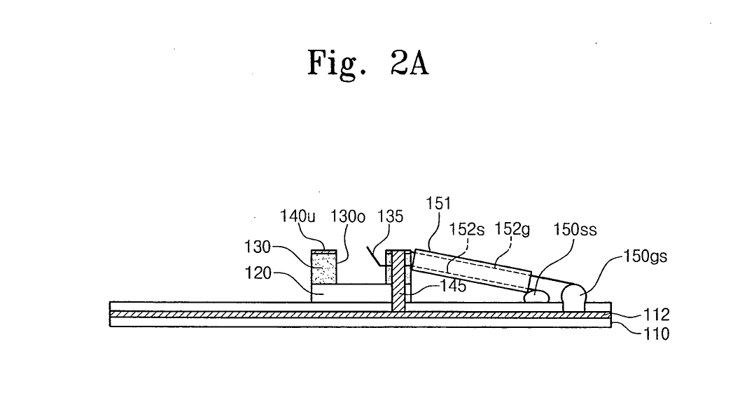

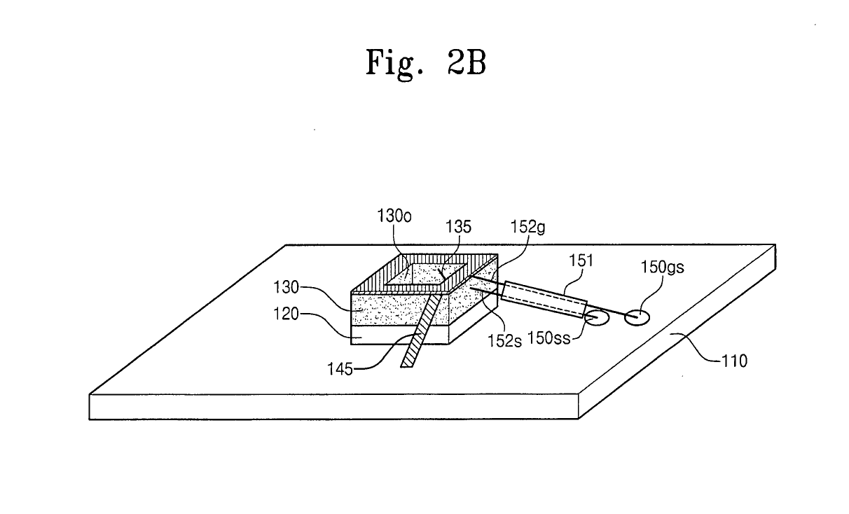

FIGS. 2A and 2B are a cross-sectional view and a perspective view, respectively, illustrating an embodiment of a probe card of a semiconductor test apparatus according to an aspect of the present invention. The probe card can include a printed circuit board (PCB) 110 in which a signal wiring (not shown) and a first ground plate 112 are provided, needle fixtures 120 and 130, a second ground plate 140u, a plurality of needles 135, a plurality of signal lines 152s, a plurality of ground lines 152g, and a connecting electrode 145. For simplification of the figures, only one of the plurality of needles 135 and only one of the plurality of signal lines 152s are illustrated in the figures.

The signal wiring and the first ground plate 112 can be provided in the PCB 110. The first ground plate 112 can include copper (Cu).

A quadrangular lower needle fixture 120 having a predetermined size can be mounted at the center of the PCB 110. The lower needle fixture 120 can be provided to insulate the PCB 110 from the plurality of needles 135 and from the plurality of signal lines 152s. Under various conditions of a process for testing semiconductor devices, the lower needle fixture 120 can serve to tightly couple the PCB 110 with an upper needle fixture 130. The lower needle fixture 120 can include ceramic.

The plurality of needles 135 corresponding to electrode pads of semiconductor devices can be arranged on the upper needle fixture 130 to achieve a fixed structure. The upper needle fixture 130 can be mounted on the lower needle fixture 120 to fix the plurality of needles 135. That is, the upper needle fixture 130 can serve to prevent the position variation of the arranged plurality of needles 135 even when an external force is applied to the arranged plurality of needles 135. Each of the plurality of needles 135 corresponding to electrode pads of semiconductor devices can have one end inclined at a predetermined angle, i.e., can a exhibit cantilever shape. The upper needle fixture 130 can have an opening 130o needed to repair the plurality of needles 135. Accordingly, the upper needle fixture 130 can exhibit a quadrangular frame having the opening 130o. The upper needle fixture 130 can include epoxy. The plurality of needles 135 can include a material selected from the group comprising tungsten (W), tungsten alloy (W-alloy), and platinum (Pt).

Each of the plurality of needles 135 has another end that can be electrically connected to the signal wiring included in the PCB 110 by the plurality of signal lines 152s. The plurality of signal lines 152s can be connected to the signal wiring provided in the PCB 110 by a solder 150ss for signal line. Each of the plurality of signal lines 152s can include a material selected from the group comprising tungsten (W), tungsten alloy (W-alloy), and platinum (Pt). The solder 150ss for signal line can include tin-silver alloy (Sn—Ag alloy).

The second ground plate 140u can be mounted on the upper needle fixture 130. The second ground plate 140u can include copper (Cu). The first and second ground plates 112 and 140u can be connected to each other by the plurality of ground lines 152g and the connecting electrode 145.

The plurality of ground lines 152g can connect the first and second ground plates 112 and 140u to each other. The plurality of ground lines 152g can be connected to the first ground plate 112 in the PCB 110 by a solder 150gs for ground line. Each of plurality of the ground lines 152g can include a material selected from the group comprising tungsten (W), tungsten alloy (W-alloy), and platinum (Pt). The solder 150gs for ground line can include tin-silver alloy (Sn—Ag alloy). Thus, the plurality of signal lines 152s can have the plurality of ground lines 152g functioning as references, respectively.

The connecting electrode 145 can connect the first and second ground plates 112 and 140u to each other. The connecting electrode 145 can include copper (Cu). The second ground plate 140u is connected to the first ground plate 112 by the connecting electrode 145, so that both ends of each of the plurality of ground lines 152g can be grounded. Thus, sufficient reference can be provided to effectively reduce loss of a signal transmitted by the plurality of signal lines 152s corresponding to the plurality of ground lines 152g.

The plurality of signal lines 152s and the plurality of ground lines 152g, which correspond to each other, can be insulated from each other by a coating material 151. The coating material 151 can be a type of a coaxial cable. Accordingly, the plurality of signal lines 152s and the plurality of ground lines 152g, which correspond to each other, can be prevented from creating a short-circuit between a signal line and a ground line wound on the coaxial cable or short-circuit with adjacent signal lines 152s and adjacent ground lines 152g.

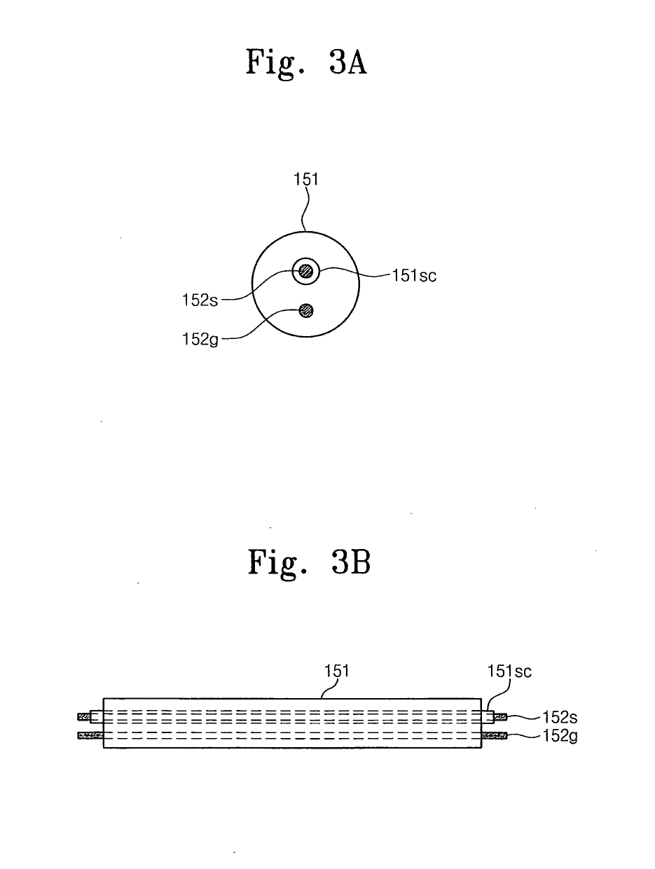

FIGS. 3A and 3B are a cross-sectional view and a top plan view illustrating, respectively, an embodiment of a coated grounded line (such as reference numeral 151) of FIG. 2B. A plurality of signal lines 152s and a plurality of ground lines 152g, which correspond to each other, can be a type of coaxial cable. A signal line 152s can be surrounded by an internal coating material 151sc. The internal coating material 151sc can include polyimide. The signal line 152s surrounded by the internal coating material 151sc and the ground line 152g can be surrounded by an external coating material 151. The external coating material 151 can also include polyimide. Since the signal line 152s is doubly surrounded by the internal coating material 151sc and the external coating material 151, signal loss caused by external environment can be suppressed.

As mentioned above, the signal line 152s and the ground line 152g are a type of coaxial cable. Therefore, the signal line 152s and the ground line 152g can be parallel with each other and spaced with a minimum distance. As a result, impedance of the signal line 152s can be reduced to enhance signal transmission efficiency of the signal line 152s.

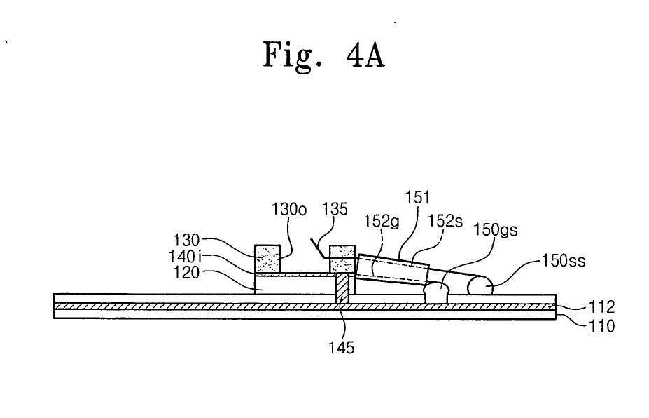

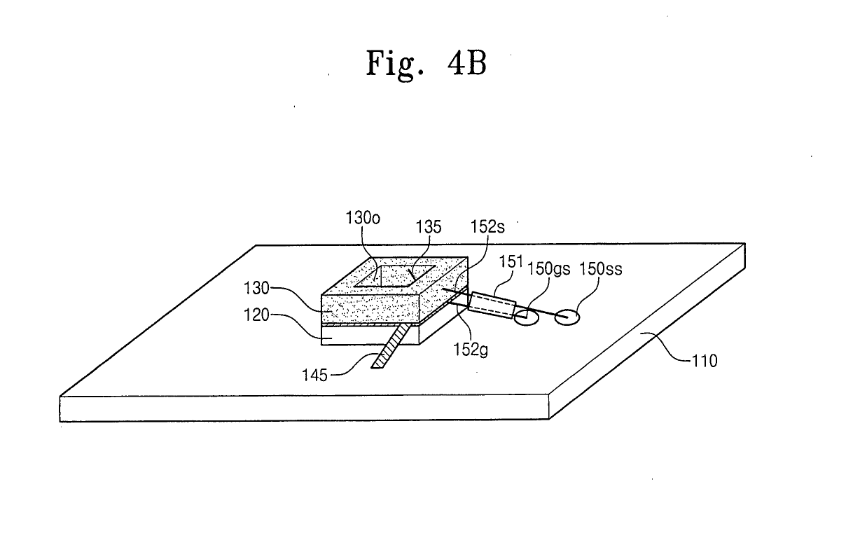

FIGS. 4A and 4B are a cross-sectional view and a perspective view, respectively, illustrating an embodiment of a probe card of a semiconductor test apparatus according to another aspects of the present invention. The probe card can include a printed circuit board (PCB) 110 in which a signal wiring (not shown) and a first ground plate 112 are provided, needle fixtures 120 and 130, a second ground plate 140i, a plurality of needles 135, a plurality of signal lines 152s, a plurality of ground lines 152g, and a connecting electrode 145. For simplification of the figures, only one of the plurality of needles 135 and only one of the plurality of signal lines 152s are illustrated in the figures.

The signal wiring and the first ground plate 112 can be provided in the PCB 110. The first ground plate 112 can include copper (Cu).

A quadrangular lower needle fixture 120 having a predetermined size can be mounted at the center of the PCB 110. The lower needle fixture 120 can be provided to insulate the PCB 110 from the plurality of needles 135 and from the plurality of signal lines 152s. Under various conditions of a process for testing semiconductor devices, the lower needle fixture 120 can serve to tightly couple the PCB 110 with an upper needle fixture 130. The lower needle fixture 120 can include ceramic.

The plurality of needles 135 corresponding to electrode pads of semiconductor devices can be arranged on the upper needle fixture 130 to achieve a fixed structure. The upper needle fixture 130 can be mounted on the lower needle fixture 120 to fix the plurality of needles 135. That is, the upper needle fixture 130 can serve to prevent the position variation of the arranged plurality of needles 135 even when an external force is applied to the arranged plurality of needles 135. Each of the plurality of needles 135 corresponding to electrode pads of semiconductor devices can have one end inclined at a predetermined angle, i.e., can exhibit a cantilever shape. The upper needle fixture 130 can have an opening 130o needed to repair the plurality of needles 135. Accordingly, the upper needle fixture 130 can exhibit a quadrangular frame having the opening 130o. The upper needle fixture 130 can include epoxy. The plurality of needles 135 can include a material selected from the group comprising tungsten (W), tungsten alloy (W-alloy), and platinum (Pt).

Each of the plurality of needles 135 has another end that can be electrically connected to the signal wiring included in the PCB 110 by the plurality of signal lines 152s. The plurality of signal lines 152s can be connected to the signal wiring provided in the PCB 110 by a solder 150ss for signal line. Each of the plurality of signal lines 152s can include a material selected from the group comprising tungsten (W), tungsten alloy (W-alloy), and platinum (Pt). The solder 150ss for signal line can include tin-silver alloy (Sn—Ag alloy).

A second ground plate 140i can be provided between the lower needle fixture 120 and the upper needle fixture 130. The second ground plate 140i can include copper (Cu). The first ground plate 112 and the second ground plate 140i can be connected to each other by the plurality of ground lines 152g and the connecting electrode 145.

The plurality of ground lines 152g can connect the first and second ground plates 112 and 140i to each other. The plurality of ground lines 152g can be connected to the first ground plate 112 in the PCB 110 by a solder 150gs for ground line. Each of the plurality of ground lines 152g can include a material selected from the group comprising tungsten (W), tungsten alloy (W-alloy), and platinum (Pt). The solder 150gs for ground line can include tin-silver alloy (Sn—Ag alloy). Thus, the plurality of signal lines 152s can include the plurality of ground lines 152g functioning as references, respectively.

The connecting electrode 145 can connect the first and second ground plates 112 and 140i to each other. The connecting electrode 145 can include copper (Cu). The second ground plate 140i is connected to the first ground plate 112 by the connecting electrode 145, so that both ends of each of the respective plurality of ground lines 152g can be grounded. Thus, sufficient reference can be provided to effectively reduce loss of a signal transmitted by the plurality of signal lines 152s corresponding to the plurality of ground lines 152g.

The plurality of signal lines 152s and the plurality of ground lines 152g, which correspond to each other, can be insulated from each other by a coating material 151. The coating material 151 can be a type of a coaxial cable, for example. Accordingly, the signal lines 152s and the ground lines 152g, which correspond to each other, can be prevented from forming a short-circuit between a signal line and a ground line wound on the coaxial cable or short-circuit with adjacent signal lines 152s and adjacent ground lines 152g.

A table, i.e., TABLE 1 below, comparatively shows characteristics of probe cards of conventional semiconductor test apparatuses and semiconductor test apparatuses in accordance with aspects of the present invention (or “Preferred” in TABLE 1).

TABLE 1

| | Impedance (L) | Inductance | Capacitance |
|---|---|---|---|
| Conventional | 200 Ω | 65 nH | 1.62 pF |
| Preferred | 75 Ω | 65 nH | 11.55 pF |

According to TABLE 1, impedance satisfies the EQUATION 1 below:

$$Z = \sqrt{\frac{L}{C}} \qquad EQUATION 1$$

wherein Z is impedance, L is inductance, and C is capacitance.

In terms of electrical characteristics, the most ideal value of impedance is about 50Ω. However, it is practically impossible to have an ideal impedance value. Hence, as the impedance value approaches 50Ω, loss of a transmitted signal can be reduced.

In order to reduce an impedance value from “200Ω” of the conventional art, an inductance value must be lowered or a capacitance value must be raised. Since the inductance value is an inherent property of a material, it cannot change without application a new material. As a result, the impedance value can be lowered by raising the capacitance value.

According to the present embodiments, a ground line having both ends grounded is added to a signal line of a probe card of a semiconductor test apparatus. Thus, a capacitance value can be raised to achieve a lowered impedance value (e.g., about 75Ω).

As described above, the signal line and the ground line are a type of coaxial cable. Therefore, the signal line and the ground line can be parallel with each other and spaced with a minimum distance. As a result, impedance of the signal line can be reduced to enhance signal transmission efficiency of the signal line.

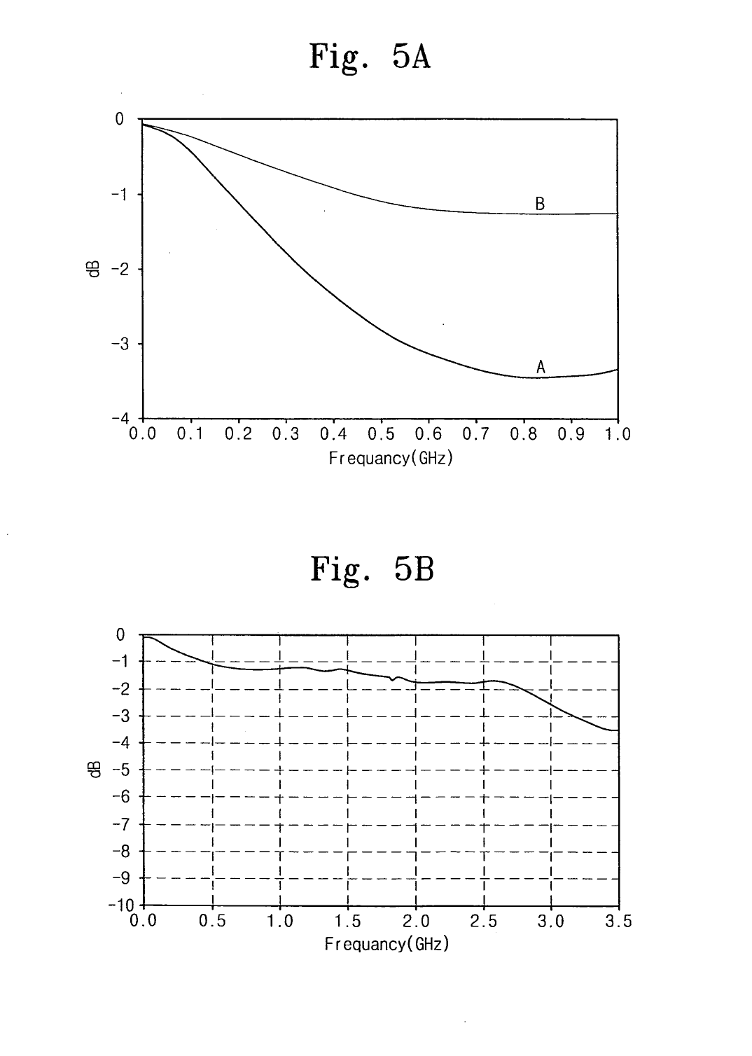

FIGS. 5A and 5B are graphs showing measured signal transmission characteristics in the frequency domain of probe cards of semiconductor test apparatuses according to aspects of the present invention.

The graph of FIG. 5A shows measured values of signal transmission characteristics at a low frequency band (e.g., 0-1 GHz) for probe cards of conventional and inventive semiconductor test apparatuses. The values are measured using a vector network analyzer (VNA). A lower characteristic curve “A” is for a probe card of a conventional semiconductor test apparatus, while an upper characteristic curve “B” is for a probe card of a semiconductor test apparatus according to the aspects of the present invention.

Referring to the curve “A” of FIG. 5A, a decibel (dB) surpasses “−3 dB” that is the reference decibel at which loss of a transmitted signal of 550 MHz or more becomes higher than 50 percent. For this reason, signal transmission is not smooth. Therefore, it is difficult to accurately evaluate operation of a semiconductor device that is formed in a semiconductor wafer and requires a signal of 550 MHz or more during a test of the semiconductor device.

Referring to the curve “B” of FIG. 5A, a decibel (dB) does not surpasses “−3 dB” that is the reference decibel at which loss of a transmitted signal of a low frequency band (0-1 GHz) becomes higher than 50 percent. Therefore, it is not difficult to evaluate operation of a semiconductor device that is formed in a semiconductor wafer and requires a signal of a low frequency band (e.g., 0-1 GHz) during a test of the semiconductor device.

The graph of FIG. 5B shows measured values of signal transmission characteristics at a high frequency band (0-3.5 GHz) for a probe card of a semiconductor test apparatuses according to the aspects of the present invention. Referring to the curve of FIG. 5B, a decibel (dB) surpasses “−3 dB” that is the reference decibel at which loss of a transmitted signal of 3.16 GHz or more becomes higher than 50 percent. Therefore, it is not difficult to evaluate operation of a semiconductor device that is formed in a semiconductor wafer and requires a signal of a wide frequency band (0-3.16 GHz) during a test of the semiconductor device.

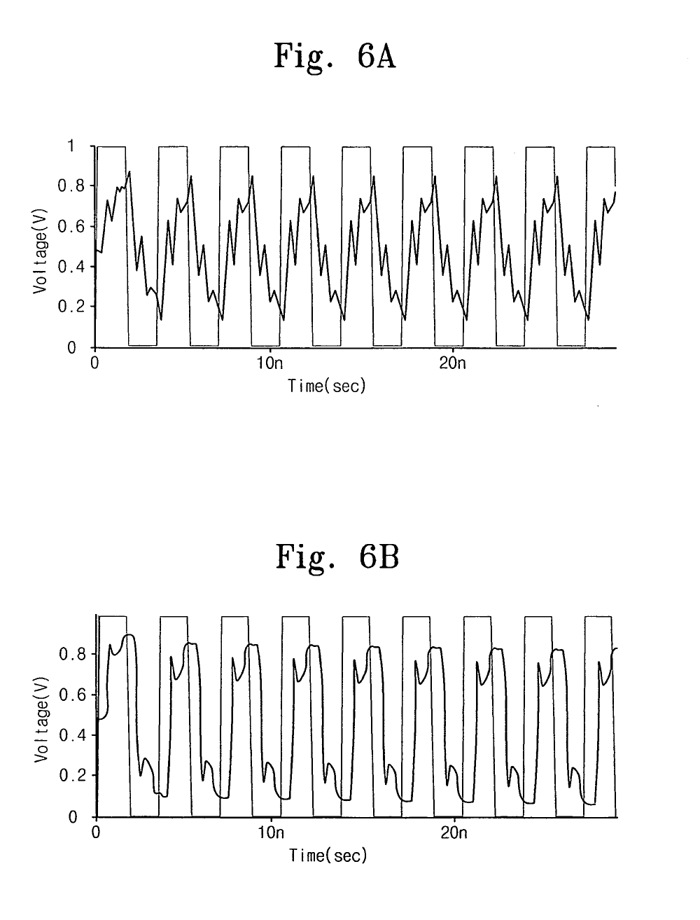

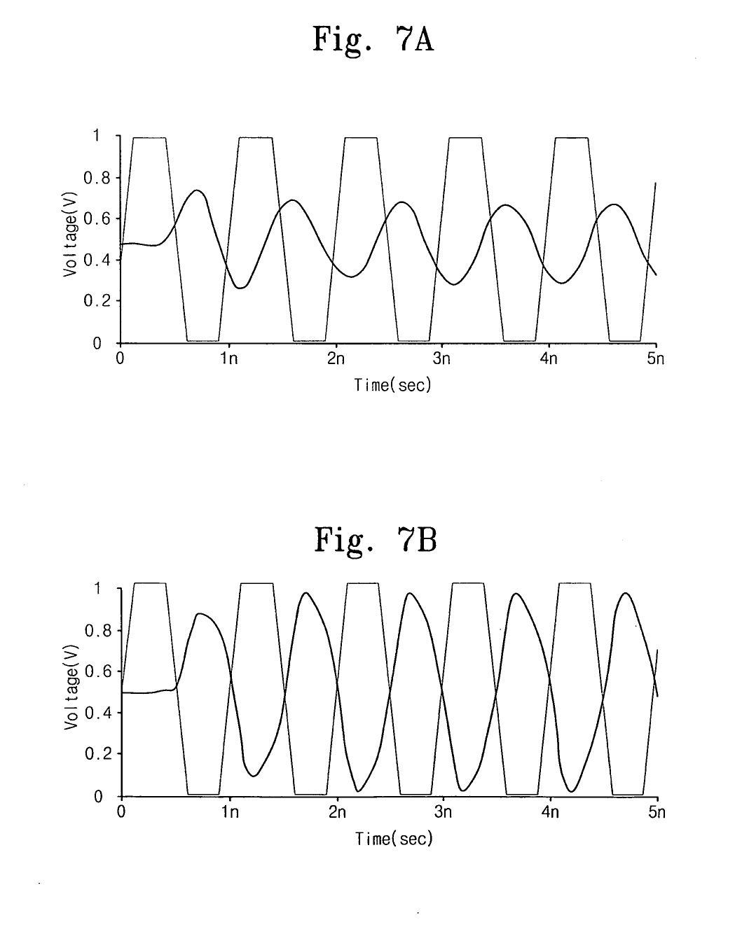

FIGS. 6A and 7A are graphs showing measured signal transmission characteristics in the time domain of probe cards of conventional semiconductor test apparatuses, and FIGS. 6B and 7B are graphs showing measured signal transmission characteristics in the time domain of probe cards of semiconductor test apparatuses according to aspects of the present invention.

Graphs of FIGS. 6A and 6B show the results when inputting a transmitted signal of low frequency band under the conditions: slew rate 300 MHz, amplitude 1V, and rising time 0.2 ns. FIGS. 6A and 6B show the results for probe cards of semiconductor test apparatuses that are conventional and that are in accordance with aspects of the present invention, respectively.

As shown in FIG. 6A, an input transmitted signal is a sine-wave signal, but the measured result is that the transmitted signal is considerably lost and distorted. On the other hand, as shown in FIG. 6B, an input transmitted signal is a sine-wave signal and the measured result is that the transmitted signal is only slightly lost and distorted. In other words, the signal loss and distortion of FIG. 6B are significantly less than those of FIG. 6A.

Graphs of FIGS. 7A and 7B show the results when inputting a transmitted signal of high frequency band under the conditions: slew rate 1 GHz, amplitude 1V, and rising time 0.2 ns. FIGS. 7A and 7B show the results for probe cards of semiconductor test apparatuses conventional and that are in accordance with aspects of the present invention, respectively.

As shown in FIG. 7A, an input transmitted signal is a sine-wave signal, but the measured result is that the transmitted signal is considerably lost. On the other hand, as shown in FIG. 7B, an input transmitted signal is a sine-wave signal and the measured result is that the transmitted signal is only slightly lost. In other words, the signal loss of FIG. 7B are significantly less than that of FIG. 7A. The transmitted signal loss of FIGS. 7A and 7B is smaller than that of FIGS. 6A and 6B because the signal of FIGS. 7A and 7B is a signal of high frequency band.

To sum up, loss and distortion of a transmitted signal are suppressed during a test to enhance test efficiency and to provide a probe card that is applicable to a semiconductor device requiring a high frequency band signal, i.e., to broaden a test range.

While the foregoing has described what are considered to be the best mode and/or other preferred embodiments, it is understood that various modifications can be made therein and that the invention or inventions may be implemented in various forms and embodiments, and that they may be applied in numerous applications, only some of which have been described herein. It is intended by the following claims to claim that which is literally described and all equivalents thereto, including all modifications and variations that fall within the scope of each claim.

What is claimed is:

1. A probe card of a semiconductor test apparatus comprising:
a printed circuit board (PCB) in which a signal wiring and a first ground plate are provided;
a needle fixture mounted to the PCB and configured to fix a plurality of needles;
a second ground plate provided on the needle fixture;
a plurality of signal lines connecting the plurality of needles to corresponding wiring in the signal wiring;
a plurality of ground lines connecting the first ground plate to a first position of the second ground plate and corresponding to the plurality of signal lines; and
a connecting electrode connecting the first ground plate to a second position of the second ground plate.

2. The probe card as recited in claim 1, wherein the first ground plate includes copper (Cu).

3. The probe card as recited in claim 1, wherein the second ground plate includes copper (Cu).

4. The probe card as recited in claim 1, wherein the needle includes a material selected from a group consisting of tungsten (W), tungsten alloy (W-alloy), and platinum (Pt).

5. The probe card as recited in claim 1, wherein the needle fixture comprises a lower needle fixture and an upper needle fixture.

6. The probe card as recited in claim 5, wherein the lower needle fixture includes ceramic.

7. The probe card as recited in claim 5, wherein the upper needle fixture includes an opening formed therein to expose the plurality of needles.

8. The probe card as recited in claim 5, wherein the upper needle fixture includes epoxy.

9. The probe card as recited in claim 5, wherein the second ground plate is mounted on the upper needle fixture.

10. The probe card as recited in claim 5, wherein the second ground plate is provided between the lower needle fixture and the upper needle fixture.

11. The probe card as recited in claim 1, wherein the signal line includes a material selected from a group consisting of tungsten (W), tungsten alloy (W-alloy), and platinum (Pt).

12. The probe card as recited in claim 1, wherein the ground line includes a material selected from a group consisting of tungsten (W), tungsten alloy (W-alloy), and platinum (Pt).

13. The probe card as recited in claim 1, wherein each signal line and each ground line that correspond to each other are insulated with a coaxial cable.

14. The probe card as recited in claim 1, wherein the connecting electrode includes copper (Cu).

15. A probe card of a semiconductor test apparatus comprising:
a printed circuit board (PCB) in which a signal wiring and a first ground plate are provided;
a needle fixture mounted to the PCB and configured to fix a plurality of needles, wherein the needle fixture comprises a lower needle fixture and an upper needle fixture and the upper needle fixture includes an opening formed therein to expose the plurality of needles;
a second ground plate provided on the needle fixture;
a plurality of signal lines connecting the plurality of needles to corresponding wiring in the signal wiring;
a plurality of ground lines connecting the first ground plate to a first position of the second ground plate and corresponding to the plurality of signal lines; and
a connecting electrode connecting the first ground plate to a second position of the second ground plate,
wherein each signal line and each ground line that correspond to each other are insulated with a coaxial cable.

16. The probe card as recited in claim 15, wherein the upper needle fixture includes epoxy.

17. The probe card as recited in claim 15, wherein the second ground plate is provided between the lower needle fixture and the upper needle fixture.

18. A method of making a probe card of a semiconductor test apparatus comprising:
providing a printed circuit board (PCB) having a signal wiring and a first ground plate;
mounting a needle fixture to the PCB, which is configured to fix a plurality of needles, wherein the needle fixture comprises a lower fixture and an upper fixture and the upper needle fixture includes an opening formed therein to expose the plurality of needles;
providing a second ground plate on the needle fixture;
connecting the plurality of needles to corresponding wiring in the signal wiring with a plurality of signal lines;
connecting the first ground plate to a first end of the second ground plate and corresponding to the plurality of signal lines with a plurality of ground lines; and
connecting the first ground plate to a second end of the second ground plate with a connecting electrode.

19. The method as recited in claim 18, wherein the second ground plate is provided on the upper needle fixture.

20. The method as recited in claim 18, wherein the second ground plate is provided between the lower needle fixture and the upper needle fixture.
